(19) United States
(12) Patent Application Publication
(10) Pub. No.: US 2026/0293228 A1
(43) Pub. Date: Sep. 24, 2026

(54) SEMICONDUCTOR DEVICE

(71) Applicant: Minebea Power Semiconductor Device Inc., Ibaraki (JP)

(72) Inventors: Haruka SHIMIZU, Tokyo (JP); Takeru SUTO, Tokyo (JP); Hiroshi MIKI, Tokyo (JP); Yuki TSUJIKAWA, Tokyo (JP)

(21) Appl. No.: 19/473,886

(22) PCT Filed: Feb. 1, 2024
(86) PCT No.: PCT/JP2024/003295

§ 371 Date: Oct. 9, 2025

(30) Foreign Application Priority Data
Apr. 20, 2023 (JP) 2023-069198

(51) Int. Cl. H10D 62/10; H10D 30/66; H10D 62/60

(52) U.S. Cl. CPC H10D 62/107; H10D 30/668; H10D 62/60

(57) ABSTRACT

A semiconductor device includes a drain region having a first conductivity type; a drift region having the first conductivity type, disposed above the drain region, and having a lower impurity concentration than the drain region; a body region having a second conductivity type and disposed above the drift region; a source region having the first conductivity type and disposed above the body region; a channel region having the second conductivity type and in contact with the body region and the source region; a gate insulating film in contact with the channel region; a gate electrode in contact with the gate insulating film; a JFET region having the first conductivity type and disposed between the two body regions; and a low lifetime region having the first conductivity type, not overlapping the JFET region, disposed between the body region and the drift region, and containing the second conductivity type impurity.

### TECHNICAL FIELD

The present invention relates to a semiconductor device.

### BACKGROUND ART

A MOSFET (metal oxide semiconductor field effect transistor), a kind of semiconductor device, is a switching element and integrates a diode. When a diode is biased in the forward direction to be in a conductive state, and then becomes reversely biased, a recovery current flows in the reverse direction due to the carriers accumulated during conduction.

Examples of the techniques for reducing the recovery current include PTL 1. PTL 1 describes, in FIG. 1 and ABSTRACT, “This semiconductor device has, on the front surface side of an N type silicon carbide substrate (1), an N type silicon carbide layer (2), a P type region (3), an N type source region (4), a P type contact region (5), a gate insulating film (6), a gate electrode (7), and a source electrode (8). The semiconductor device has a drain electrode (9) on the rear surface of the N type silicon carbide substrate (1). The semiconductor device has a lifetime killer-introduced region (10) at least on the whole interface between the N type silicon carbide layer (2) and the bottom surface of the P type region (3), said lifetime killer-introduced region having a lifetime killer introduced therein. The lifetime killer is introduced into the whole interface between the N type silicon carbide layer (2) and the bottom surface of the P type region (3) by injecting helium or protons from the rear surface side of the N type silicon carbide substrate (1) before providing the drain electrode (9), after manufacturing the surface structure of an element on the front surface side of the N type silicon carbide substrate (1). Consequently, a reverse recovery loss of a PN diode integrated in the semiconductor device can be reduced.”.

Further, PTL 1 describes, in paragraph 0007, “Since the lifetime killer, serving as a recombination center for minority carriers, is introduced into the whole interface between the first conductivity type silicon carbide layer and the bottom surface of the second conductivity type region, minority carriers are extinguished at high speed when the integrated PN diode is turned Off.”.

Further, PTL 1 describes, in FIG. 10 and paragraph 0079, “As shown in FIG. 10, the semiconductor device according to the third embodiment is a semiconductor device according to the first embodiment shown in FIG. 1 in which the lifetime killer is also introduced into the Jfet region between the adjacent P type regions 3. That is, the lifetime killer-introduced region 10 is provided in the whole region at the same depth as the interface between the N type silicon carbide layer 2 and the bottom surface of the P type region 3.”.

### CITATION LIST

### Patent Literature

PTL 1: WO 2016/039071 A1

### SUMMARY OF INVENTION

### Technical Problem

However, in PTL 1, the lifetime killer to reduce the recovery current is formed by lattice defects made by implanting helium or protons. Therefore, there is a problem that a mask is required to partly form the lifetime killer-introduced region (10) as shown in FIG. 1 of PTL 1, so that such a semiconductor device is difficult to produce, and difficult to produce with high accuracy. In addition, when the lifetime killer-introduced region (10) is formed in the whole surface as shown in FIG. 10 of PTL 1, there is a problem that the current path on MOSFET operation is included therein so that the carrier amount in the semiconductor is reduced also in the current path on MOSFET operation and the on-resistance is increased on MOSFET operation.

An object of present invention is to provide a semiconductor device that is easy to produce and can reduce recovery current while suppressing an increase in the on-resistance of the MOSFET.

### Solution to Problem

In order to solve the above problems, the semiconductor device of the present invention includes: a drain region having a first conductivity type; a drift region having a first conductivity type, disposed above the drain region, and having a lower impurity concentration than the drain region; a body region having a second conductivity type and disposed above the drift region; a source region having a first conductivity type and disposed above the body region; a channel region having a second conductivity type and being in contact with the body region and the source region; a gate insulating film in contact with the channel region; a gate electrode in contact with the gate insulating film; a drain electrode electrically connected to the drain region; electrode electrically connected to the source region; a JFET region having a first conductivity type and disposed above the drift region and between the two adjacent body regions; and a low lifetime region having a first conductivity type, disposed between the body region and the drift region, and containing a second conductivity type impurity in a range of 6×10¹¹ cm⁻² or more and 1×10¹³ cm⁻² or less, wherein the low lifetime region is not disposed between the JFET region and the drift region.

### Advantageous Effects of Invention

The semiconductor device of the present invention, including a low lifetime region having a first conductivity type and containing a second conductivity type impurity, is easy to produce and can reduce recovery current while suppressing an increase in the on-resistance of the MOSFET.

### BRIEF DESCRIPTION OF DRAWINGS

FIG. 1 is a cross-sectional view of a semiconductor device of Example 1.

FIG. 2 is an impurity concentration profile against the depth in the Z1-Z1′ direction in FIG. 1 in the semiconductor device of Example 1.

FIG. 3 is a cross-sectional view of a semiconductor device of Example 2.

FIG. 4 is a perspective view of a semiconductor device of Example 3.

FIG. 5 is a cross-sectional view in the X1-X1′ in FIG. 4 in the semiconductor device of Example 3.

FIG. 6 is a cross-sectional view in the X2-X2′ in FIG. 4 in the semiconductor device of Example 3.

FIG. 7 is a cross-sectional view in the Y1-Y1′ in FIG. 4 in the semiconductor device of Example 3.

FIG. 8 is a cross-sectional view of a semiconductor device of Example 4.

### DESCRIPTION OF EMBODIMENTS

Hereinafter, examples of the present invention will be described with reference to the drawings. In the drawings and the examples, the same or similar components are denoted by the same reference signs, and redundant description is omitted.

### EXAMPLE 1

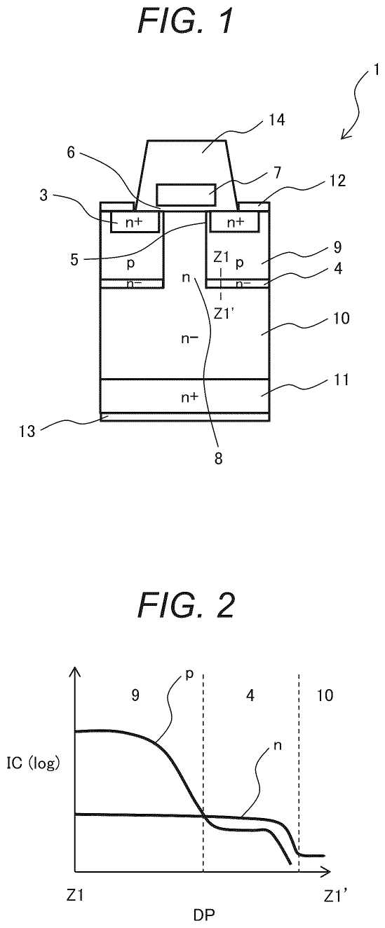

FIG. 1 is a cross-sectional view of a semiconductor device of Example 1.

A semiconductor device 1 of Example 1 includes: a drain region 11 having a first conductivity type; a drift region 10 having a first conductivity type, disposed above the drain region 11, and having a lower impurity concentration than the drain region 11; a body region 9 having a second conductivity type and disposed above the drift region 10; a source region 3 having a first conductivity type and disposed above the body region 9; and a channel region 5 having a second conductivity type and being in contact with the body region 9 and the source region 3.

Although Example 1 describes a case where the first conductivity type is n type and the second conductivity type is p type as an example, the present invention is not limited thereto. Optionally, the first conductivity type is p type and the second conductivity type is n type.

In addition, the semiconductor device 1 of Example 1 includes: a gate insulating film 6 in contact with the channel region 5; a gate electrode 7 in contact with the gate insulating film 6; a drain electrode 13 electrically connected to the drain region 11; and a source electrode 12 electrically connected to the source region 3.

Here, the semiconductor device 1 of Example 1 is a planar type MOSFET, and the gate insulating film 6 and the gate electrode 7 are disposed above the channel region 5.

The semiconductor device 1 of Example 1 includes: a JFET region 8 having a first conductivity type and disposed above the drift region 10 and between the two adjacent body regions 9. The JFET region 8 preferably has a higher impurity concentration than the drift region 10, to which the present invention is not limited, and may have as high an impurity concentration as the drift region 10.

In addition, the semiconductor device 1 of Example 1 includes an interlayer insulating film 14, but is not limited thereto.

The structures described hereinbefore are general MOSFET structures, and the detailed structures are not limited to those illustrated in FIG. 1. The semiconductor device 1 of Example 1 can be formed, for example, with an n+ type SiC substrate, but is not limited thereto. In addition, the semiconductor device 1 of Example 1 can be produced by a general production method of a semiconductor device, such as forming an n+ type drain region 11 with an n+ type SiC substrate, and forming an n− type drift region 10 through epitaxial growth. Therefore, detailed descriptions will be omitted.

Here, in order to reduce recovery current in the integrated diode of the MOSFET, the semiconductor device 1 of Example 1 has a low lifetime region 4 having a first conductivity type, disposed between the body region 9 and the drift region 10, and containing a second conductivity type impurity in a range of 6×10¹¹ cm⁻² or more and 1×10¹³ cm⁻² or less. In addition, since the portion between the JFET region 8 and the drift region 10 serves as the current path on MOSFET operation, the low lifetime region 4 is not disposed in the portion to avoid an increase in on-resistance. That is, the low lifetime region 4 is formed so as not to overlap the JFET region 8 serving as the current path on MOSFET operation. When the second conductivity type is p type, the low lifetime region 4 preferably has aluminum as the second conductivity type impurity. Although aluminum and boron are known as a p type impurity, aluminum is particularly effective in reducing the lifetime of holes, and thus is effective in reducing recovery current.

When description is made with reference to an example where the second conductivity type is p type, it is effective for reducing recovery current that holes as a carrier have a low lifetime. Here, when merely an n type low lifetime region 4 is formed between the body region 9 and the drift region 10, the effect of low lifetime is small. When the n type impurity concentration is increased, the effect of low lifetime is increased, but when the n type impurity concentration is excessively increased, there is a problem that the withstand voltage is lowered.

Therefore, in the semiconductor device 1 of Example 1, the n type low lifetime region 4 contains a p type impurity, thereby achieving a low lifetime of holes as a carrier, while the net total impurity amount obtained by subtracting the p type impurity concentration from the n type impurity concentration is a low concentration. The body region 9 also includes a p type impurity, but the body region 9 also includes many holes. Therefore, the p type impurity in the body region 9 does not contribute to reducing recovery current. Therefore, it is effective for reducing recovery current to include a p type impurity in the n type low lifetime region 4.

In the method in which helium or protons are implanted to form lattice defects to achieve a low lifetime as in the related art, there is a problem that it is difficult to partly form the low lifetime region; and when the low lifetime region is formed on the entire surface of a wafer, there is a problem that the current path on MOSFET operation is included therein so that the on-resistance is increased on MOSFET operation. However, in the case of the low lifetime region 4 having a first conductivity type and containing a second conductivity type impurity in Example 1, it is easy to precisely form the low lifetime region 4 such that the low lifetime region 4 does not include the current path on MOSFET operation, as compared to partly implanting helium or protons, and thereby it is possible to suppress an increase in the on-resistance due to the added low lifetime region 4.

The low lifetime region 4 having a first conductivity type and containing a second conductivity type impurity can be produced by back-implanting an impurity. The difference between the first conductivity type impurity concentration and the second conductivity type impurity concentration is the concentration of the low lifetime region 4. The order for the back-implanting is not particularly limited, and either the first conductivity type impurity or the second conductivity type impurity may precede the other. The back-implanting may be performed also as a step for forming the JFET region 8 having a first conductivity type.

The net total impurity amount in the low lifetime region 4 is preferably 15% or less of the total impurity amount in the drift region 10, the net total impurity amount being obtained by subtracting the second conductivity type impurity concentration from the first conductivity type impurity concentration. In order to increase the amount of the second conductivity type impurity in the low lifetime region 4, the dose amount of the back-implanted first conductivity type impurity needs to be increased. However, when the dose amount is increased, the net total impurity amount is increased and the withstand voltage is lowered. When the net total impurity amount in the low lifetime region 4 is larger than 15% of the total impurity amount in the drift region 10, the withstand voltage is significantly lowered. Therefore, 15% or less is preferable.

In the low lifetime region 4, the dose amount of the second conductivity type impurity is preferably 6×10¹¹ cm⁻² or more in order to increase the effect of reducing recovery current, and the dose amount thereof is preferably in a range of 1×10¹³ cm⁻² or less in order to suppress the back-implanting amount of the first conductivity type impurity.

Since the path of the recovery current passes between the body region 9 and the drift region 10, the low lifetime region 4 is preferably formed on the entire lower surface of the body region 9.

FIG. 2 is an impurity concentration profile against the depth in the Z1-Z1′ direction in FIG. 1 in the semiconductor device of Example 1. In FIG. 2, the vertical axis represents the impurity concentration IC on the log scale, and the horizontal axis represents the depth DP. In FIG. 2, “n” and “p” indicate the impurity concentration profiles of n type (first conductivity type) and p type (second conductivity type), respectively.

As shown in FIG. 2, in the low lifetime region 4 having a first conductivity type and containing a second conductivity type impurity, the profile of the second conductivity type impurity concentration (p in FIG. 2) preferably has a flat region in the depth direction. As a result, the low lifetime region 4 having a first conductivity type and containing a second conductivity type impurity can be formed deeply (thick). The profile having such a flat region can be formed by, for example, channeling implantation, in which the crystal axis of the semiconductor substrate and the direction of ion implantation are matched. FIG. 2 shows an example in which the implantation of the second conductivity type impurity is divided into two times: the implantation of the second conductivity type impurity to form the body region 9 is performed by normal ion implantation; and the implantation of the second conductivity type impurity to form the low lifetime region 4 having a flat region is performed by channeling implantation.

Example 1 shows an example in which the JFET region 8 is n type, the body region 9 is p type, the drift region 10 and the low lifetime region 4 are n− type (low concentration), and the source region 3 and the drain region 11 are n+ type (high concentration). However, the present invention is not limited thereto as long as the operation intended in Example 1 can be realized. For example, the JFET region 8 may be n− type (low concentration).

In addition, examples of each component in Example 1 will be described below, but the present invention is not limited thereto as long as the operation intended in Example 1 can be realized.

The drain region 11 is a Sic wafer and contains about 1×10¹⁸ cm⁻³ of an n type impurity (nitrogen). The thickness is in a range of 50 to 500 um, and is about 150 um in a typical example.

The drift region 10 is an epitaxial layer of SiC formed on the SiC wafer and contains an n type impurity (nitrogen) in a range of 1×10¹⁴ cm⁻³ to 1×10¹⁷ cm⁻³. The thickness is in a range of 5 to 100 um. In a typical example, the n type impurity is 1×10¹⁶ cm³ and the thickness is 10 um. The withstand voltage in the off state is determined by the drift region 10. The withstand voltage is 1200 V in the specification of a typical example.

A plurality of body regions 9 is formed in a stripe shape, and is formed by ion implantation of a p type impurity (aluminum). The depth is about 1 um, and the concentration is about 1×10¹⁸ cm⁻³.

The source region 3 is formed inside the body region 9, and has a depth (thickness) of about 0. 4 um and a concentration of about 1×10²⁰ cm⁻³.

The channel region 5 is formed on the surface of the body region 9, and is formed by ion implantation of a p type impurity (aluminum). The depth is about 0.2 um, and the concentration is about 1×10¹⁷ cm⁻³. The channel region 5 may have as high a concentration as the body region 9. In this case, a part of the body region 9 functions as the channel region 5.

The gate insulating film 6 is a film containing SiO₂ as a main component, and has a thickness of about 50 nm. Near the interface between SiC and SiO₂, nitrogen is introduced in order to improve interface characteristics.

The gate electrode 7 is a polysilicon containing an n type impurity in a high concentration.

The low lifetime region 4 is formed on the entire lower surface of the body region 9, and is formed by back-implanting an n type impurity to the bottom of the body region 9. The low lifetime region 4 contains 6×10¹¹ cm⁻² or more of aluminum, which is a p type impurity.

The source electrode 12 and the drain electrode 13 are made of metal such as aluminum.

### EXAMPLE 2

Example 2 is a modification of Example 1, and is an example in which Example 1 is applied to a trench-type MOFSET.

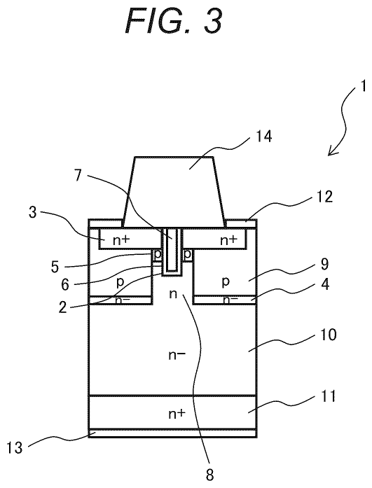

FIG. 3 is a cross-sectional view of a semiconductor device of Example 2.

A semiconductor device 1 of Example 2 has a trench 2 formed to a position deeper than the source region 3 and the channel region 5, wherein the gate insulating film 6 and the gate electrode 7 are disposed inside the trench 2.

The detailed structures are not limited to those illustrated in FIG. 3. For example, the trench 2 may be disposed between the two body regions 9 as illustrated in FIG. 3 such that both side surfaces of the trench 2 are in contact with the channel regions 5, or one side surface of the trench 2 may be in contact with the channel region 5.

The MOSFET having a trench structure has a low channel resistance, and therefore can be used at a high current density. At this time, the hall current flowing through the integrated diode also increases, and thus recovery current increases. Therefore, it is highly necessary to reduce recovery current, and the effect that recovery current can be reduced by the low lifetime region 4 is increased.

### EXAMPLE 3

Example 3 is a modification of Example 1, and is an example in which Example 1 is applied to a trench MOSFET having a vertical channel fin structure.

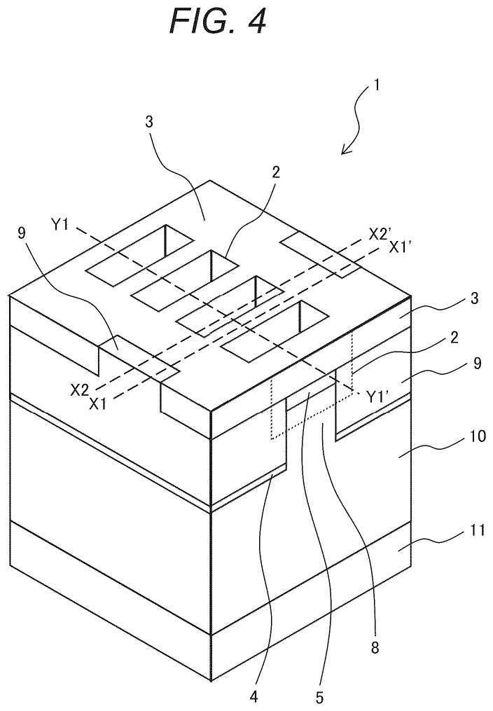

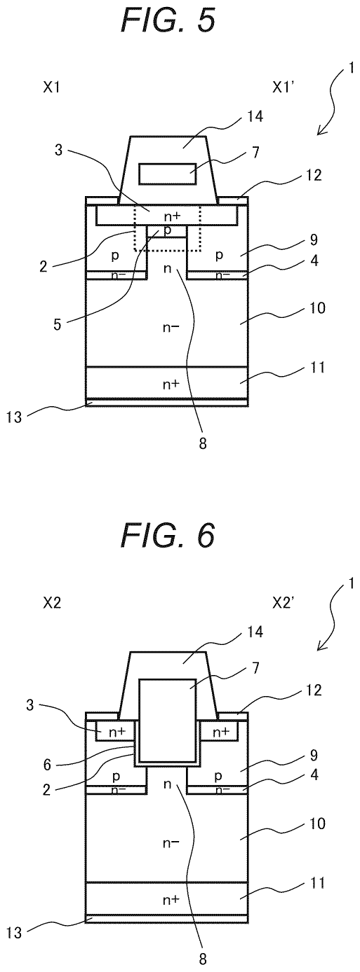

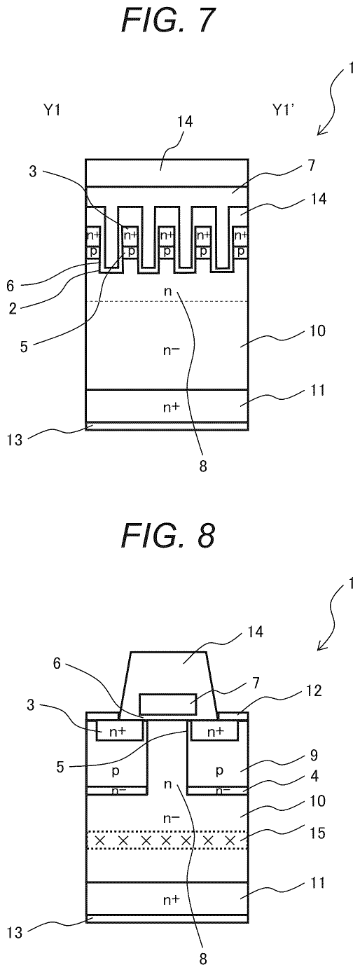

FIG. 4 is a perspective view of a semiconductor device of Example 3. FIG. 5 is a cross-sectional view in the X1-X1′ in FIG. 4 in the semiconductor device of Example 3. FIG. 6 is a cross-sectional view in the X2-X2′ in FIG. 4 in the semiconductor device of Example 3. FIG. 7 is a cross-sectional view in the Y1-Y1′ in FIG. 4 in the semiconductor device of Example 3. In FIG. 4, the gate electrode 7, the gate insulating film 6, the interlayer insulating film 14, the source electrode 12, and the drain electrode 13 are omitted. In addition, the trench 2 indicated by a dotted line in the cross sections of FIGS. 4 and 5 virtually indicates the position corresponding to the trench 2 in order to describe the positional relationship between other components and the trench 2.

A semiconductor device 1 of Example 3 has a plurality of trenches 2 formed to a position deeper than the source region 3 and the channel region 5, wherein the source region 3 and the channel region 5 each have a fin structure region divided by the plurality of trenches 2, and the gate insulating film 6 and the gate electrode 7 are disposed inside the plurality of trenches 2. The detailed structures are not limited to those illustrated in FIGS. 4 to 7.

The trench MOSFET having a vertical channel fin structure, having a trench structure, has a low channel resistance as in Example 2, and therefore can be used at a high current density. Therefore, since recovery current is increased as in Example 2, it is highly necessary to reduce recovery current, and the effect that recovery current can be reduced by the low lifetime region 4 is increased.

Examples of each component in Example 3 will be described below, but the present invention is not limited thereto as long as the operation intended in Example 3 can be realized.

The channel region 5 is a region sandwiched between the two body regions 9, and is formed immediately below the source region 3. The channel region 5 is formed by ion implantation of a p type impurity (aluminum). The depth is about 0.6 um, and the concentration is about 1×10¹⁷ cm⁻³. The distance from the bottom of the source region 3 to the bottom of the channel region 5 is the channel length.

The trench 2 has a short side of about 0.5 um and a long side of about 1.5 um, and the distance between the trenches 2 is about 0.5 um. A plurality of trenches 2 is formed so as to step over the body regions 9, and the side wall of the trench 2 on the long side serves as a channel surface.

As illustrated in FIGS. 4 and 5, the semiconductor device 1 of Example 3 includes, in plan view, a plurality of trenches 2 having a longitudinal direction in a first direction, having a short direction in a second direction, and arranged in the second direction. The source region 3 partly has a fin structure region divided by the plurality of trenches 2. The channel region 5 is in contact with the lower surface of the fin structure region of the source region 3, and has a fin structure divided by the plurality of trenches 2.

As illustrated in FIGS. 5 to 7, the gate electrodes 7 disposed inside the trenches 2 are connected to each other outside the trenches 2. An interlayer insulating film 14 is formed between the portion where the gate electrodes 7 are connected to each other and the source regions 3. The interlayer insulating film 14 is formed so as to cover the upper portion and the side portion of the portion where the gate electrodes 7 are connected to each other. The gate electrode 7 can be formed of, for example, polysilicon.

As illustrated in FIG. 5, the trench 2 is formed such that the length in the longitudinal direction overlaps the body regions 9 on both sides sandwiching the JFET region 8. The depth of the trench 2 is shallower than the body region 9 and deeper than the channel region 5.

In the semiconductor device 1 of Example 3, a gate drive signal is input to the gate electrode 7 inside the trench 2 for control, so that a channel current flows in the channel region 5 having a fin structure in the vertical direction. That is, the semiconductor device 1 of Example 3 is a trench MOSFET having a vertical channel fin structure. Therefore, when the trench pitch is reduced and the density of the trenches 2 is increased, the channel density can be increased, the channel resistance can be reduced, and the on-resistance can be reduced.

### EXAMPLE 4

Example 4 is a modification of Example 1, and is an example of a combination with a technique of irradiating protons or helium.

FIG. 8 is a cross-sectional view of a semiconductor device of Example 4.

In the semiconductor device 1 of Example 3, in addition to the configuration of Example 1, the drift region 10 partly has a lattice defect region 15 containing protons or helium and having a lattice defect.

When the low lifetime region 4 having a first conductivity type and containing a second conductivity type impurity of Example 1 is combined with the lattice defect region 15, recovery current is further reduced. Since the low lifetime region 4 is provided, the dose amount of the lattice defect region 15 can be reduced as compared with the case where the lattice defect region 15 is provided alone. In addition, the lattice defect region 15 can be formed at a position away from the body region 9. When the lattice defect region 15 is provided on the entire surface, there is a disadvantage that the current path on MOSFET operation is included therein so that the on-resistance on MOSFET operation is increased. However, in Example 4, since the dose amount of the lattice defect region 15 can be reduced, the increase in the on-resistance on MOSFET operation can be reduced.

Examples of each component in Example 4 will be described below, but the present invention is not limited thereto as long as the operation intended in Example 4 can be realized.

The lattice defect region 15 is a region in which lattice defects are formed by proton or helium irradiation. The lifetime can be reduced by the lattice defect region 15. For example, as the depth direction, the irradiation is performed in the vicinity of the center in the depth direction of the drift region 10, and the dose amount is preferably in a range of 1×10¹⁰ cm⁻² to 1×10¹² cm⁻², and is typically about 5×10¹⁰ cm⁻².

Although examples of the present invention have been described above, the present invention is not limited to the configurations described in the examples, and various modifications can be made within the scope of the technical idea of the present invention. In addition, some or all of the configurations described in each example may be applied in combination. For example, Example 4 may be applied to Example 2 or Example 3.

### REFERENCE SIGNS LIST

1 semiconductor device
2 trench
3 source region
4 low lifetime region
5 channel region
6 gate insulating film
7 gate electrode
8 JFET region
9 body region
10 drift region
11 drain region
12 source electrode
13 drain electrode
14 interlayer insulating film
15 lattice defect region
IC impurity concentration
DP depth

1. A semiconductor device comprising:
a drain region having a first conductivity type;
a drift region having a first conductivity type, disposed above the drain region, and having a lower impurity concentration than the drain region;
a body region having a second conductivity type and disposed above the drift region;
a source region having a first conductivity type and disposed above the body region;
a channel region having a second conductivity type and being in contact with the body region and the source region;
a gate insulating film in contact with the channel region;
a gate electrode in contact with the gate insulating film;
a drain electrode electrically connected to the drain region;
a source electrode electrically connected to the source region;
a JFET region having a first conductivity type and disposed above the drift region and between the two adjacent body regions; and
a low lifetime region having a first conductivity type, disposed between the body region and the drift region, and containing a second conductivity type impurity in a range of 6×10¹¹ cm⁻² or more and 1×10¹³ cm⁻² or less,
wherein the low lifetime region is not disposed between the JFET region and the drift region.

2. The semiconductor device according to claim 1, wherein a net total impurity amount in the low lifetime region is 15% or less of a total impurity amount in the drift region, the net total impurity amount being obtained by subtracting a second conductivity type impurity concentration from a first conductivity type impurity concentration.

3. The semiconductor device according to claim 1, wherein the low lifetime region has a region in which a profile of a second conductivity type impurity concentration is flat in a depth direction.

4. The semiconductor device according to claim 1, wherein the first conductivity type is n type, and the second conductivity type is p type.

5. The semiconductor device according to claim 4, wherein the low lifetime region has aluminum as the second conductivity type impurity.

6. The semiconductor device according to claim 1, wherein the drift region partly has a lattice defect region containing protons or helium and having a lattice defect.

7. The semiconductor device according to claim 1, wherein the JFET region has a higher impurity concentration than the drift region.

8. The semiconductor device according to claim 1, wherein the gate insulating film and the gate electrode are disposed above the channel region.

9. The semiconductor device according to claim 1,
having a trench formed to a position deeper than the source region and the channel region,
wherein the gate insulating film and the gate electrode are disposed inside the trench.

10. The semiconductor device according to claim 1,
having a plurality of trenches formed to a position deeper than the source region and the channel region,
wherein the source region and the channel region each have a fin structure region divided by the plurality of trenches, and
the gate insulating film and the gate electrode are disposed inside the plurality of trenches.
